(19) United States
(12) Patent Application Publication
(10) Pub. No.: US 2025/0174590 A1
(43) Pub. Date: May 29, 2025

(54) SUBSTRATE MOUNTING METHOD, SUBSTRATE AND IMAGE FORMING APPARATUS

(71) Applicant: CANON KABUSHIKI KAISHA, Tokyo (JP)

(72) Inventors: HIROSHI FUSE, Tokyo (JP); MASAMICHI IIDA, Kanagawa (JP); TSUYOSHI YAMAGUCHI, Chiba (JP); TADASHI IKEMOTO, Tokyo (JP); TAKAYUKI YOSHIHAMA, Ibaraki (JP); SHIMPEI TANIGAWA, Chiba (JP); MISAO OGISHIMA, Chiba (JP); TAKASHI KAMEO, Ibaraki (JP)

(21) Appl. No.: 18/933,062

(22) Filed: Oct. 31, 2024

(30) Foreign Application Priority Data
Nov. 28, 2023 (JP) 2023-200422

(51) Int. Cl. H01L 23/00; G03G 15/00; H01L 23/49; H01L 25/065

(52) U.S. Cl. CPC H01L 24/16; G03G 15/80; H01L 23/49; H01L 24/11; H01L 24/81; H01L 25/0655; H01L 2224/11849; H01L 2224/16225; H01L 2224/81815; H01L 2924/1432

(57) ABSTRACT

A substrate mounting method includes steps for applying a first cream solder on a solder surface for a chip component by using a first mask, for mounting a jumper wire, a step for applying a second cream solder for the jumper wire by using a second mask, for mounting the chip component on the first cream solder, a step for soldering the jumper wire and the chip component by melting the first and second cream solders by a reflow process, for mounting a lead component from a surface opposite to the solder surface, for attaching a cover member which covers at least a part of the solder surface including the jumper wire and the chip component soldered in the reflow process, and for soldering the lead component by conveying the substrate in a flow soldering tank in a state in which the cover member is attached.

### FIELD OF THE INVENTION AND RELATED ART

The present invention relates to a substrate mounting method, a substrate and an image forming apparatus, and relates to an electrical substrate mounting method in which a conductive pattern is provided on one side, for example.

Conventionally, flow solder mounting (soldering) is performed in some electrical substrates in a case that lead components and chip components are mounted together. Part (A) and part (B) of FIG. 9 are views illustrating solder bridges of chip components in a conventional soldering method, upper side figures are top views and lower side figures are sectional views. Part (A) of FIG. 9 is a view showing a state of a solder bridge. Chip components 1 are mounted adjacent to each other on a substrate 2 on which components are mounted. In flow solder mounting, the chip components 1 in a solder tank may leave solder between each component and cause solder bridges 3 when the chip components 1 exit from the solder tank. In order to suppress the occurrence of the solder bridges 3, it is necessary to ensure wide spaces between each component, as shown in part (B) of FIG. 9. However, by ensuring the wide spaces between each component, a larger substrate area is required for the spaces. Further, many patterns (signal patterns) for transmitting signals are laid around CPU, etc. and many lead jumpers are disposed across the signal patterns. The lead jumpers are also required to be disposed spaced apart from the chip components 1 to suppress the occurrence of the solder bridges 3. In conventional examples, since a solder bridge and a substrate miniaturization are in a trade-off relation, there is a problem in that it is difficult to solve both issues together.

In response to the above issue, it is an object of the present invention to suppress solder bridging and to miniaturize a substrate.

### SUMMARY OF THE INVENTION

In order to solve the problems which are described above, the present invention is provided with following configurations.

(1) A substrate mounting method for mounting a component on a substrate including a conductive pattern, the substrate mounting method comprising: a first application step for covering a solder surface of the substrate on which the conductive pattern is provided by a first mask plate and applying a first cream solder to solder a chip component on the solder surface; a first mount step for mounting a jumper wire connecting between patterns of the conductive pattern; a second application step for covering the solder surface by a second mask plate and applying a second cream solder to solder the jumper wire mounted on the solder surface; a second mount step for mounting the chip component on the first cream solder applied in the first application step; a reflow step for soldering the jumper wire and the chip component which are mounted by melting the first cream solder and the second cream solder by a reflow process; a third mount step for mounting a lead component from a surface opposite to the solder surface; a protection step for attaching a cover member which covers at least a part of an area of the solder surface including the jumper wire and the chip component which are soldered in the reflow process; and a flow step for soldering the lead component by conveying the substrate in a flow soldering tank in a state in which the cover member is attached.

(2) A substrate including a solder surface provided with a conductive pattern, the substrate comprising: a first mounting area where a lead component is soldered on a surface opposite to the solder surface; a second mounting area where a chip component is soldered on the solder surface; and a jumper wire soldered on the second mounting area by a reflow process.

(3) An image forming apparatus for forming an image on a recording material, the image forming apparatus comprising the substrate according to above (2).

Further features of the present invention will become apparent from the following description of exemplary embodiments with reference to the attached drawings.

### BRIEF DESCRIPTION OF THE DRAWINGS

FIG. 1 is a schematic sectional view showing a configuration of an image forming apparatus according to an embodiment.

Part (A) and part (B) of FIG. 2 are views illustrating a substrate according to the embodiment.

Part (A), part (B), part (C) and part (D) of FIG. 3 are views illustrating an application step and a mount step of cream solder of a chip component according to the embodiment.

Part (A), part (B), part (C) and part (D) of FIG. 4 are views illustrating an application step of cream solder according to the embodiment.

Part (A) and part (B) of FIG. 5 are a sectional view showing a mounted state and a sectional view showing a reflow soldered state according to the embodiment.

FIG. 6 is a sectional view showing a state that lead components are mounted according to the embodiment.

Part (A) and part (B) of FIG. 7 are a perspective view showing a flow area and a reflow area and a perspective view of the substrate on which a frame jig is mounted according to the embodiment.

FIG. 8 is a sectional view showing details of a state that the frame jig is mounted according to the embodiment.

Part (A) and part (B) of FIG. 9 are views illustrating solder bridging of the chip components according to a conventional example.

### DESCRIPTION OF THE EMBODIMENTS

### First Embodiment

### [Image Forming Apparatus]

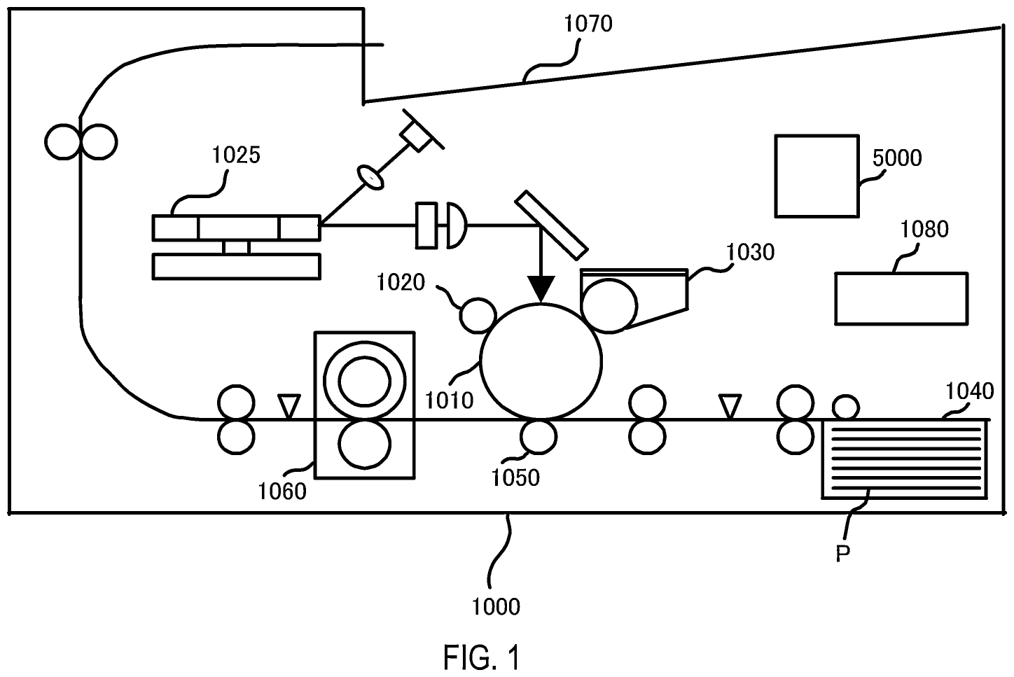

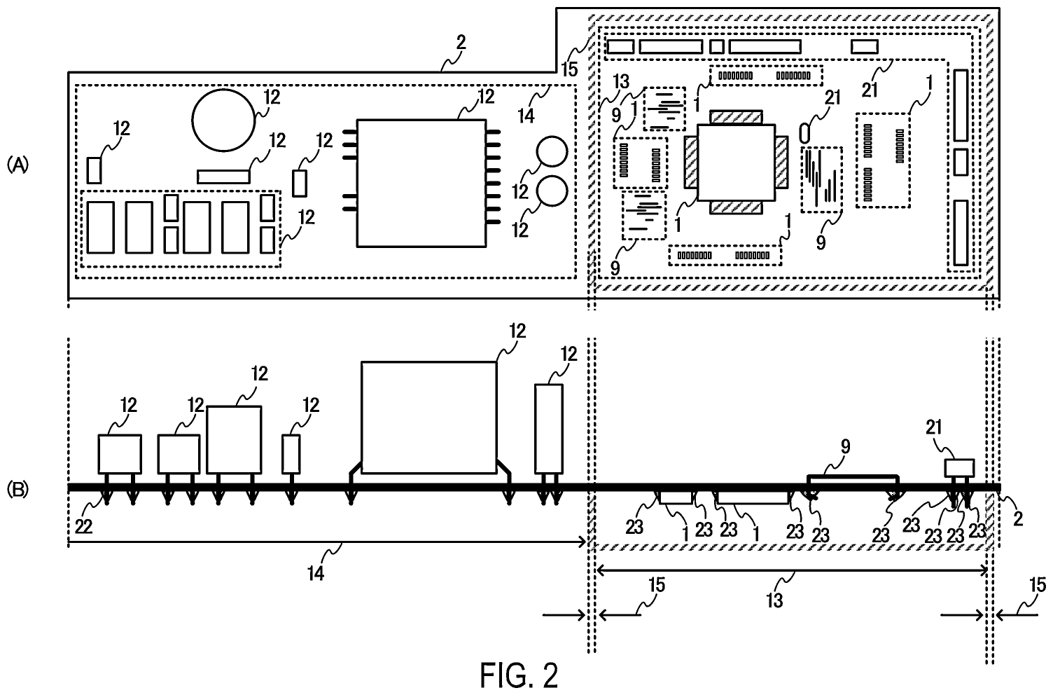

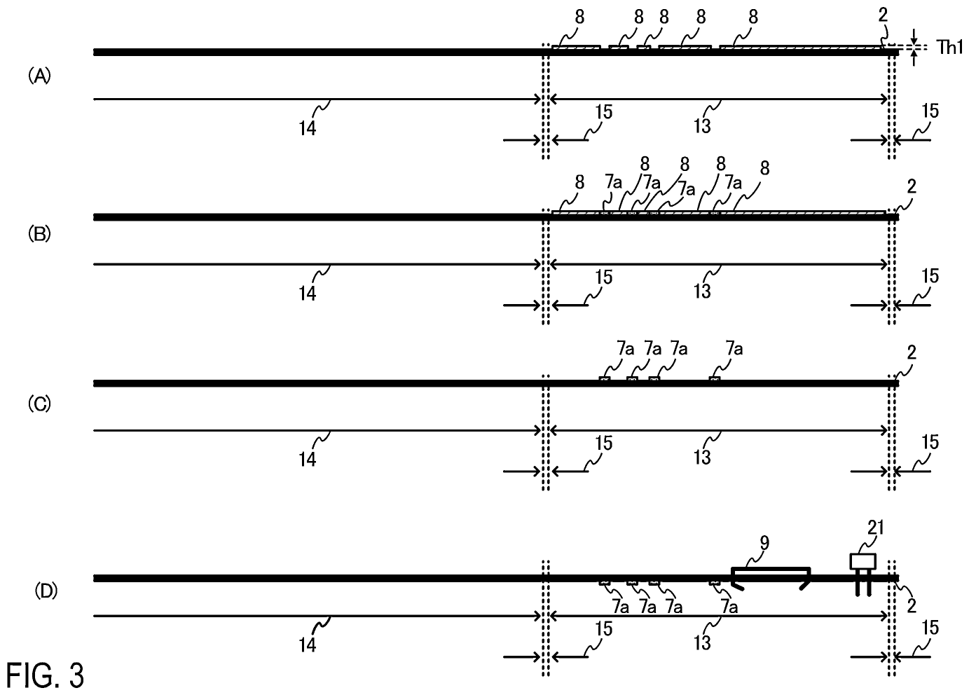

In an embodiment of the present invention, a laser beam printer (hereinafter simply referred to as a printer) will be described as an example of an electronic device to which a substrate is applied. In FIG. 1, a schematic configuration of a laser beam printer is shown as an example of an image forming apparatus. The laser beam printer 1000 (hereinafter, referred to as a printer 1000) is provided with a photosensitive drum 1010, a charging portion 1020 and a developing portion 1030. The photosensitive drum 1010 is an image bearing member on which an electrostatic latent image is formed. The charging portion 1020 uniformly charges the photosensitive drum 1010. An optical scanning device 1025 which is an exposure means forms an electrostatic latent image by scanning a laser beam on the photosensitive drum 1010 according to image data. A developing portion 1030 forms a toner image by developing the electrostatic latent image which is formed on the photosensitive drum 1010 with toner. The toner image which is formed on the photosensitive drum 1010 (on the image bearing member) is transferred to a sheet P as a recording material which is supplied from a cassette 1040 by a transfer portion 1050, and the unfixed toner image which is transferred to the sheet P is fixed by the fixing device 1060 and discharged to a tray 1070. An image forming portion is configured of the photosensitive drum 1010, the charging portion 1020, the developing portion 1030 and the transfer portion 1050. Further, the printer 1000 is also provided with a power source device 1080 and the power source device 1080 supplies power to driving portions such as a motor and a control portion 5000. The control unit 5000 includes a CPU (Central Processing Unit) (not shown) and controls image forming operations by the image forming portion, conveying operations of the sheet P, etc. Based on a required voltage accuracy of the CPU, a standard for voltage accuracy in the embodiment is, for example, 5V±5% (Vmin=4.75V, Vmax=5.25V). After a predetermined period of time since the printer 1000 completes a printing operation, the printer 1000 transitions to a standby state in which it is possible to execute the printing operation immediately. After a further predetermined period of time, the printer 1000 transitions from the standby state to a sleep state which is a low power consumption mode in order to reduce power consumption during a waiting time. The printer 1000 is capable of transitioning three states, which are the sleep state and the standby state as a second mode and a printing state as a first mode, and the control portion 5000 transitions the printer 1000 to each state. Incidentally, the image forming apparatus, to which the substrate of the present invention can be applied, is not limited to a configuration which is illustrated in FIG. 1.

### [Circuit Substrate]

The printer 1000 is mainly provided with circuit substrates which will be described below. The circuit substrates are installed in, for example, a low voltage power source device which generates DC voltage from AC voltage, a DC controller which controls the printer 1000, a high voltage power source device which generates high voltage which is used in an electrophotographic process. Further, they are installed in, for example, a driving circuit which supplies power to actuators which convey the sheet P and drive a toner cartridge and a fixing roller, a sensor circuit which detects various states, etc. In the embodiment, as an example, a process of mounting a low voltage power source device (the power source device 1080 which is described above) and a DC controller (the control portion 5000 which is described above) on a single substrate will be described.

Part (A) and part (B) of FIG. 2 are views illustrating a substrate according to the embodiment, to which the present invention can be applied. Part (A) of FIG. 2 is a top view illustrating the substrate 2 according to the embodiment. The substrate 2 is a single side mounting substrate which is provided with conductive patterns on only one side and it is advantageous in terms of cost. In conventional single side mounting substrates, only flow process is performed, and the substrates are not miniaturized in order to prevent from occurring solder bridge. In the embodiment, it is possible to realize miniaturization even when it is a single side mounting substrate by a method which will be described below. Incidentally, a side on which the conductive patterns are provided is called a solder side, and a side which is opposite to the solder side in which a lead component which will be described below is mounted is called a mounting side. On the substrate 2, there are a flow area 14 as a first mounting area, a reflow area 13 as a second mounting area and a frame jig mounting area 15. The flow area 14 is an area in which components are mounted by flow soldering, and the reflow area 13 is an area in which components are mounted by reflow soldering. The frame jig mounting area 15 is an area for providing a frame jig to prevent solder from entering the reflow area 13 in a case of flow soldering. Here, flow soldering is a soldering step which is suitable for mounting large components and is a mounting method in which productivity is high. On the other hand, reflow soldering is a soldering step which is suitable for mounting chip components which will be described below and is a mounting method in which accuracy is high.

Mainly large lead components 12 (first lead components), such as AC connectors and power semiconductors, power transformers (transformers), electrolytic capacitors and AC filters (primary filters), are mounted in the flow area 14. Here, a lead component is a component which includes a lead wire, and is a component which is soldered on the solder surface which is opposite to the mounting surface by inserting the lead wire into a hole (through hole) which is provided on the substrate 2 from a side of the mounting surface. On the other hand, in the reflow area 13, a lead jumpers 9 as a jumper wire for straddling signal lines (connecting between the conductive patterns), the chip components 1 (first chip components) such as a CPU, a resistor and a capacitor, and small lead components 21 (second lead components) such as connector and quartz crystal are mounted. Here, a chip component is a component which is soldered directly to the solder surface of the substrate 2, and is also referred to as a component for surface mounting. In the reflow area 13, it is possible to mount components at a higher density than the flow area 14.

Part (B) of FIG. 2 is a sectional view illustrating the substrate 2. Incidentally, 23 is a reflow solder fillet and 22 is a flow solder fillet, and only some reference numerals are shown. The substrate 2 is divided into the flow area 14 and the reflow area 13, and each of components are mounted. As described above, in the reflow area 13, since it is possible to mount components with high density and greatly suppresses occurring solder bridge which occurs in flow soldering, miniaturization of the substrate and improvement of quality can be expected.

### [Dividing Area of Components]

In the following, a specific manufacturing method according to the embodiment will be described. In the substrate 2 according to the embodiment, since a low voltage power source circuit is included and many large lead components 12 are used, an inexpensive paper phenol material which is provided with copper foil on one side is used. Further, in general, since heat capacity of a lead component is large, so there are problems such as solder does not melt even when a soldered part of a lead component is heated by reflow soldering, or coating of electrolytic capacitor, etc. melts due to heat and a component is destroyed. Therefore, flow soldering is applied for a substrate which includes lead components.

Further, in a direct current controller circuit, since there are many patterns (further referred to as a signal pattern) for transmitting signals which are connected from a CPU, so connections between the patterns are made by using lead jumpers which can straddle a plurality of signal patterns. Furthermore, in the direct current controller circuit, there are many chip components, except lead jumpers.

For this reason, in the embodiment, the power source circuit is mounted in the flow area 14 and the direct current controller circuit is mounted in the reflow area 13 so that each of them is mounted dividedly, by reflow soldering the lead jumper 9 whose heat capacity is small in the reflow area 13. Further, the small lead component 21 is also mounted on the reflow area 13 by applying a kink (bending) to a lead.

### [Mounting Method of Substrate]

In the following, each step of mounting method of the substrate 2 will be described. Part (A), part (B), part (C) and part (D) of FIG. 3 are sectional views of the substrate 2 in side view. In the beginning, a cream solder 7a is applied to the solder surface of the substrate 2 in which the conductive patterns are provided, by using a thin mask plate to apply cream solder to the chip component 1 for reflow mounting (first application step). The cream solder 7a is a solder for reflow soldering. The thin mask plate 8 (first mask plate) is a thin mask plate which is used to apply the cream solder 7a (first cream solder) only to the chip component 1 which is a target. On the thin mask plate 8, there are holes in positions in which the cream solder 7a is applied, that is, in positions corresponding to lands, so that the cream solder 7a can be applied to the solder surface of the substrate 2. In other words, in the first application step, the solder side of the substrate 2 in which the conductive patterns are provided is covered with the first mask plate, and furthermore the first cream solder is applied to mount the chip components 1.

First, as shown in part (A) of FIG. 3, the thin mask plate 8 is mounted on the copper foil surface (solder surface) of the substrate 2, and as shown in part (B) of FIG. 3, the cream solder 7a is spread (squeegeed) to only target area. Then, as shown in part (C) of FIG. 3, when the thin mask plate 8 is removed from the substrate 2, the cream solder 7a is applied to the land of the chip component 1.

Part (D) of FIG. 3 is a view illustrating the mount step (first mount step) for mounting the lead jumper 9 and the small lead component 21 on the substrate 2 according to the embodiment. First, the substrate 2 to which the cream solder 7a is applied is turned over and, as shown in part (D) of FIG. 3, the lead jumper 9 is mounted and bent (clinched) so that the lead jumper 9 is not removed from the substrate 2. Then, the small lead component 21 is mounted. Incidentally, a kink is applied to the lead wire of the small lead component 21 in order to prevent the small lead component 21 from dropping out from the substrate 2.

Subsequently, a cream solder 7b is applied (second application step) by using a thick mask plate 10 (second mask plate) to apply the cream solder 7b (second cream solder) to the lead jumper 9 and the small lead component 21. On the thick mask plate 10, there are holes in positions in which the cream solder 7b is applied, that is, in positions corresponding to lands, so that the cream solder 7b can be applied to the solder surface of the substrate 2. That is, the solder surface is covered with the second mask plate and, furthermore, the cream solder 7b is applied to mount the jumper wire which is mounted. Part (A), part (B), part (C) and part (D) of FIG. 4 are views illustrating steps of applying the cream solder 7b to the lead jumper 9 and the small lead component 21. First, as shown in part (A) of FIG. 4, the substrate 2 is turned over and, as shown in part (B) of FIG. 4, the thick mask plate 10 for applying the cream solder 7b to the lead jumper 9 and the small lead component 21 is mounted.

Here, the thick mask plate 10 whose thickness is thick is used in order to apply more amount of the cream solder 7b to the lead jumper 9 and the small lead component 21 than the amount of the cream solder 7a which applies to the chip component 1.

When the thickness of the thin mask plate 8 is defined as Th1 (see part (A) of FIG. 3) and the thickness of the thick mask plate 10 is defined as Th2, a relationship between Th1 and Th2 is Th1<Th2. Incidentally, thickness refers to the thickness in a direction which is perpendicular to the plane of the substrate 2. Further, the thick mask plate 10 is provided with a hollow 10a as a recessed portion. The hollow 10a is provided so that it is at a position (in an area) which is opposed to the cream solder 7a for the chip component 1 and so that it is provided to avoid the cream solder 7a in order to protect the cream solder 7a for the chip component 1, when the thick mask plate 10 is mounted on the substrate 2.

And as shown in part (C) of FIG. 4, the cream solder 7b is squeegeed and applied only to a target area. And as shown in part (D) of FIG. 4, when the thick mask plate 10 is removed from the substrate 2, it becomes in a state that the cream solder 7b is applied to the lead jumper 9 and the land of the small lead component 21. Incidentally, since a kink is applied to the small lead component 21 for preventing them from falling out, it is possible to apply the cream solder 7b in the same method as for the lead jumper 9.

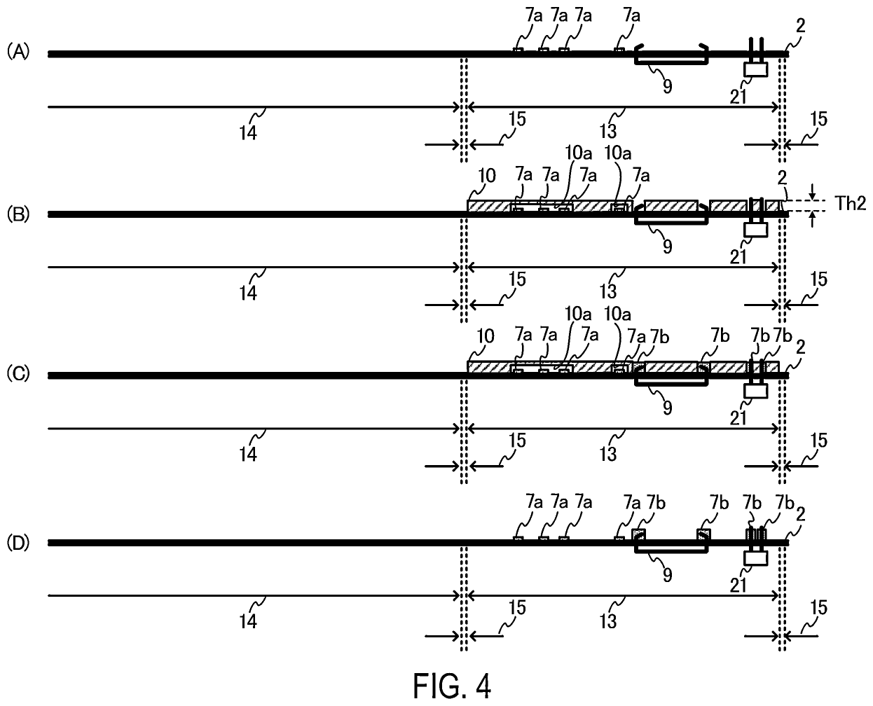

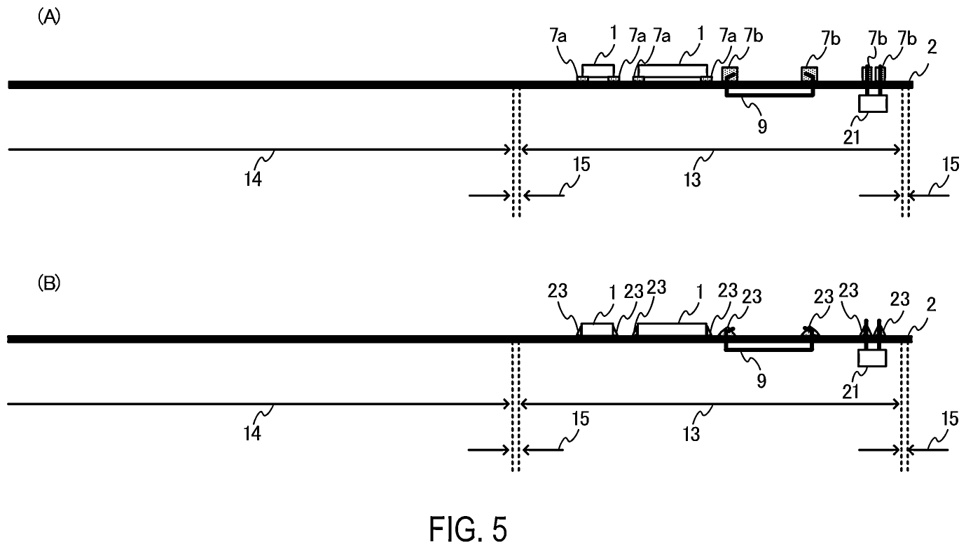

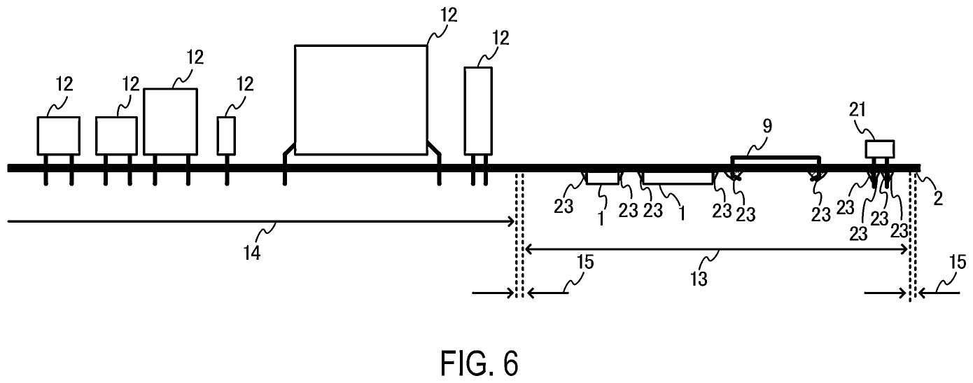

Subsequently, as shown in part (A) of FIG. 5, the chip component 1 is mounted on a surface of the substrate 2 to which the cream solder 7a is applied (second mount step). Subsequently, as shown in in part (B) of FIG. 5, the cream solder 7a and the cream solder 7b are melted in a reflow furnace, and the chip component 1, the small lead component 21 and the lead jumper 9 are mounted by a reflow process (reflow step). Then, the cream solder 7a and the cream solder 7b become fillet shapes 23 and are soldered. Subsequently, the substrate 2 which is reflow soldered is turned over and, as shown in FIG. 6, the large lead component 12 is mounted from an opposite surface of the solder surface as shown in FIG. 6 (third mounting step).

### (Frame Jig)

Subsequently, the frame jig which is used to prevent solder from entering the reflow area 13 during flow soldering. Part (A) of FIG. 7 is a perspective view of the substrate 2 when it is viewed from the bottom (solder surface side), and the bottom side is the solder surface. As shown in part (B) of FIG. 7, a frame jig 16 is mounted as a protective member (cover member) to prevent the flow solder from entering the reflow area 13 before performing flow soldering (protection step). That is, the cover member is mounted to cover at least a part of the area of the solder surface which includes the jumper wire and the chip component which are soldered in the reflow step. The frame jig 16 protects at least a part of the area of the solder surface which includes the lead jumper 9 and the lead component 21 which are soldered by the reflow process which is described above.

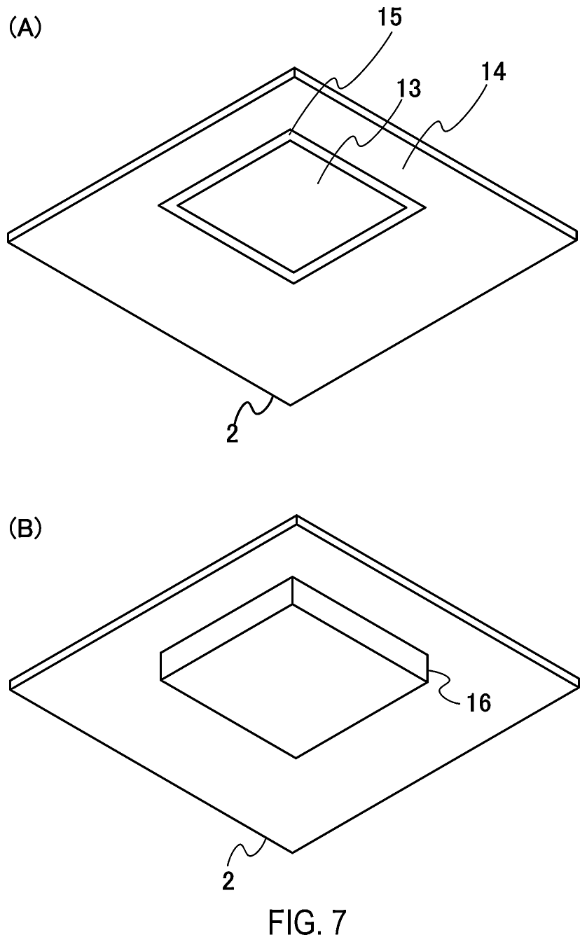

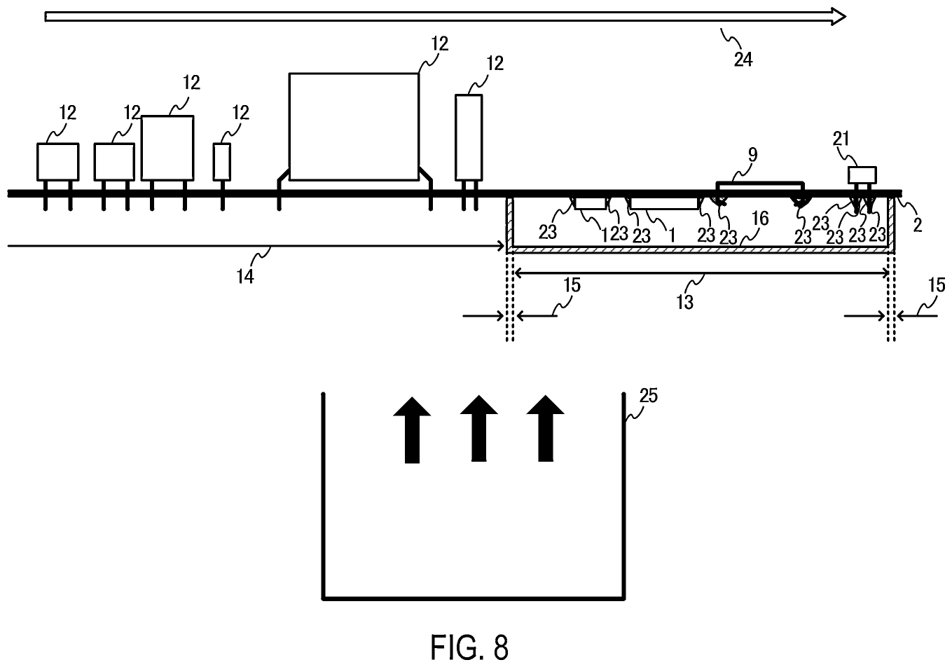

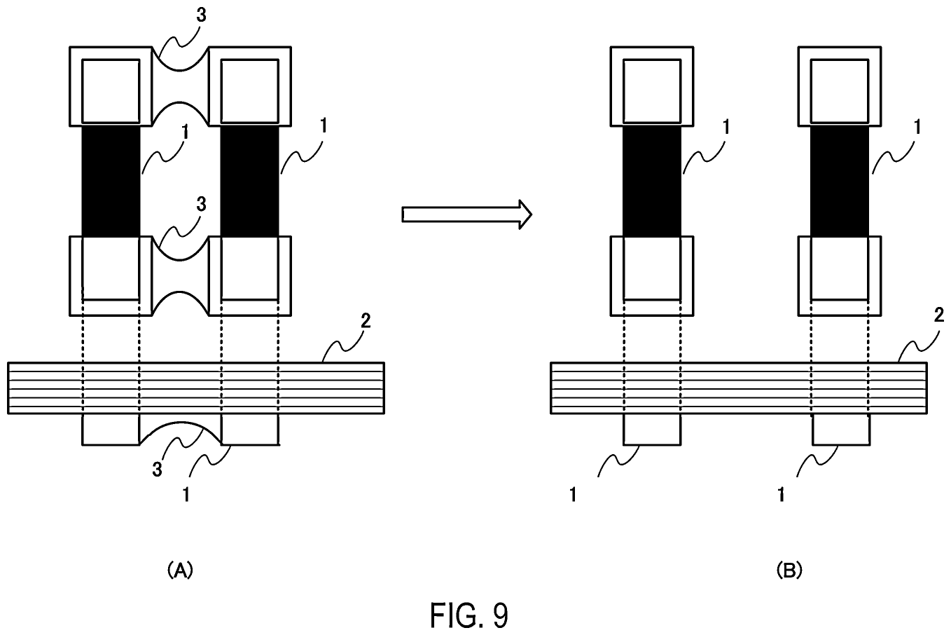

FIG. 8 is a sectional view illustrating the substrate 2 on which the frame jig is mounted and a flow solder tank 25. The large lead component 12 is mounted in the flow area 14. Incidentally, the lead jumper 9, the chip component 1 and the small lead component 21 have already been mounted in the reflow area 13. The frame jig 16 is mounted onto the frame jig mounting area 15 to enclose the reflow area 13. And the substrate 2 on which the components are mounted is conveyed (flowed) in the flow solder tank 25 in a direction which is indicated by a flow direction 24 in which the substrate 2 is moved, and the large lead component 12 is flow soldered (flow soldering step).

By performing the soldering steps which are described above, it is possible to solder densely without occurring solder bridge in the reflow area 13 which is reflow soldered, therefore, it is possible to suppress occurring solder bridge and to miniaturize the substrate.

Incidentally, since it is possible to solder the chip components and the lead jumpers by flow soldering, it is possible to obtain the same effect as in the configuration even when some of the chip components and the lead jumpers are flow soldered. Further, the lead jumper is mounted in the reflow area 13 in the configuration, however, it is possible to obtain the same effect as in the configuration even when one of the lead jumpers (first jumper line) is mounted in the reflow area 13 and the other (second jumper line) is mounted in the flow area 14. Further, not only the first lead component and the second jumper wire which are mounted by the flow process, but a second chip component may be provided in the flow area 14. Further, in the configuration, paper phenol material is used for the substrate 2, however, it is possible to obtain the same effect as in the configuration even when any other material is used as long as the substrate which uses the lead jumper.

As described above, according to the embodiment, it is possible to suppress occurring solder bridge and to miniaturize the substrate.

The disclosure of the present embodiments includes the following method and constitution examples.

### (Method 1)

A substrate mounting method for mounting a component on a substrate including a conductive pattern, the substrate mounting method comprising:
a first application step for covering a solder surface of the substrate on which the conductive pattern is provided by a first mask plate and applying a first cream solder to solder a chip component on the solder surface;
a first mount step for mounting a jumper wire connecting between patterns of the conductive pattern;
a second application step for covering the solder surface by a second mask plate and applying a second cream solder to solder the jumper wire mounted on the solder surface;
a second mount step for mounting the chip component on the first cream solder applied in the first application step;
a reflow step for soldering the jumper wire and the chip component which are mounted by melting the first cream solder and the second cream solder by a reflow process;
a third mount step for mounting a lead component from a surface opposite to the solder surface;
a protection step for attaching a cover member which covers at least a part of an area of the solder surface including the jumper wire and the chip component which are soldered in the reflow process; and
a flow step for soldering the lead component by conveying the substrate in a flow soldering tank in a state in which the cover member is attached.

### (Method 2)

The substrate mounting method according to Method 1, wherein a thickness of the first mask plate in a direction perpendicular to the substrate is thinner than a thickness of the second mask plate in the direction perpendicular to the substrate.

### (Method 3)

The substrate mounting method according to Method 1 or 2, wherein the second mask plate includes a recessed portion in an area opposite to the first cream solder applied in the first application step while the second cream solder is applied in the second application step.

### (Method 4)

The substrate mounting method according to any one of Methods 1 to 3, wherein the substrate is a single side substrate on which the conductive pattern is provided on a single side.

### (Constitution 1)

A substrate including a solder surface provided with a conductive pattern, the substrate comprising:
a first mounting area where a lead component is soldered on a surface opposite to the solder surface;
a second mounting area where a chip component is soldered on the solder surface; and
a jumper wire soldered on the second mounting area by a reflow process.

### (Constitution 2)

The substrate according to Constitution 1, wherein the lead component soldered on the first mounting area is defined as a first lead component, and further comprising
a second lead component soldered on the second mounting area.

### (Constitution 3)

The substrate according to Constitution 2, further comprising a CPU and a crystal oscillator soldered on the second mounting area.

### (Constitution 4)

The substrate according to Constitution 1, wherein the jumper wire is defined as a first jumper wire, and further comprising
a second jumper wire soldered on the first mounting area by a flow process.

### (Constitution 5)

The substrate according to Constitution 1, wherein the chip component is defined as a first chip component and the jumper wire is defined as a first jumper wire, and further comprising
a second jumper wire and a second chip component soldered on the first mounting area by a flow process.

### (Constitution 6)

The substrate according to Constitution 5, further comprising an AC connecter, a transformer, a primary filter, an electrolytic capacitor and power semiconductor soldered on the first mounting area by a flow process.

### (Constitution 7)

The substrate according to Constitution 1, wherein the lead component soldered on the first mounting area is defined as a first lead component, the chip component and the jumper wire soldered on the second mounting area are defined as a first chip component and a first jumper wire, respectively, and further comprising
a second lead component soldered on the second mounting area; and
a second jumper wire and a second chip component soldered on the first mounting area by flow process.

### (Constitution 8)

The substrate according to Constitution 1, further comprising a CPU and a crystal oscillator soldered on the second mounting area; and
an AC connecter, a transformer, a primary filter, an electrolytic capacitor and power semiconductor soldered on the first mounting area by flow process.

### (Constitution 9)

The substrate according to any one of Constitutions 1 to 8, wherein the substrate is a single side substrate on which the conductive pattern is provided on a single side.

### (Constitution 10)

An image forming apparatus for forming an image on a recording material, the image forming apparatus comprising the substrate according to any one of Constitutions 1 to 9.

### (Constitution 11)

The image forming apparatus according to Constitution 10, wherein a power source circuit for generating a DC voltage from an AC voltage is soldered on the first mounting area, and
wherein a DC controller for controlling the image forming apparatus is soldered on the second mounting area.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-200422, filed on Nov. 28, 2023, which is hereby incorporated by reference herein in its entirety.

What is claimed is:

1. A substrate mounting method for mounting a component on a substrate including a conductive pattern, the substrate mounting method comprising:
a first application step for covering a solder surface of the substrate on which the conductive pattern is provided by a first mask plate and applying a first cream solder to solder a chip component on the solder surface;
a first mount step for mounting a jumper wire connecting between patterns of the conductive pattern;
a second application step for covering the solder surface by a second mask plate and applying a second cream solder to solder the jumper wire mounted on the solder surface;
a second mount step for mounting the chip component on the first cream solder applied in the first application step;
a reflow step for soldering the jumper wire and the chip component which are mounted by melting the first cream solder and the second cream solder by a reflow process;
a third mount step for mounting a lead component from a surface opposite to the solder surface;
a protection step for attaching a cover member which covers at least a part of an area of the solder surface including the jumper wire and the chip component which are soldered in the reflow process; and
a flow step for soldering the lead component by conveying the substrate in a flow soldering tank in a state in which the cover member is attached.

2. The substrate mounting method according to claim 1, wherein a thickness of the first mask plate in a direction perpendicular to the substrate is thinner than a thickness of the second mask plate in the direction perpendicular to the substrate.

3. The substrate mounting method according to claim 1, wherein the second mask plate includes a recessed portion in an area opposite to the first cream solder applied in the first application step while the second cream solder is applied in the second application step.

4. The substrate mounting method according to claim 1, wherein the substrate is a single side substrate on which the conductive pattern is provided on a single side.

5. A substrate including a solder surface provided with a conductive pattern, the substrate comprising:
a first mounting area where a lead component is soldered on a surface opposite to the solder surface;
a second mounting area where a chip component is soldered on the solder surface; and
a jumper wire soldered on the second mounting area by a reflow process.

6. The substrate according to claim 5, wherein the lead component soldered on the first mounting area is defined as a first lead component, and further comprising
a second lead component soldered on the second mounting area.

7. The substrate according to claim 6, further comprising a CPU and a crystal oscillator soldered on the second mounting area.

8. The substrate according to claim 5, wherein the jumper wire is defined as a first jumper wire, and further comprising
a second jumper wire soldered on the first mounting area by a flow process.

9. The substrate according to claim 5, wherein the chip component is defined as a first chip component and the jumper wire is defined as a first jumper wire, and further comprising
a second jumper wire and a second chip component soldered on the first mounting area by a flow process.

10. The substrate according to claim 9, further comprising an AC connecter, a transformer, a primary filter, an electrolytic capacitor and power semiconductor soldered on the first mounting area by a flow process.

11. The substrate according to claim 5, wherein the lead component soldered on the first mounting area is defined as a first lead component, the chip component and the jumper wire soldered on the second mounting area are defined as a first chip component and a first jumper wire, respectively, and further comprising
a second lead component soldered on the second mounting area; and
a second jumper wire and a second chip component soldered on the first mounting area by flow process.

12. The substrate according to claim 5, further comprising a CPU and a crystal oscillator soldered on the second mounting area; and
an AC connecter, a transformer, a primary filter, an electrolytic capacitor and power semiconductor soldered on the first mounting area by flow process.

13. The substrate according to claim 5, wherein the substrate is a single side substrate on which the conductive pattern is provided on a single side.

14. An image forming apparatus for forming an image on a recording material, the image forming apparatus comprising the substrate according to claim 5.

15. The image forming apparatus according to claim 14, wherein a power source circuit for generating a DC voltage from an AC voltage is soldered on the first mounting area, and
wherein a DC controller for controlling the image forming apparatus is soldered on the second mounting area.
